(19) United States
(12) Patent Application Publication
(10) Pub. No.: US 2008/0206902 A1
(43) Pub. Date: Aug. 28, 2008

(54) STRESS MEASUREMENTS DURING LARGE-MISMATCH EPITAXIAL PROCESSES

(75) Inventors: David Bour, Cupertino, CA (US); Jacob Grayson, Cupertino, CA (US)

Correspondence Address: TOWNSEND AND TOWNSEND AND CREW LLP / AMAT, TWO EMBARCADERO CENTER, EIGHTH FLOOR, SAN FRANCISCO, CA, 94111-3834, US

(73) Assignee: Applied Materials, Inc., A Delaware corporation, Santa Clara, CA (US)

(21) Appl. No.: 11/678,870

(22) Filed: Feb. 26, 2007

(51) Int. Cl. H01L 21/66; B05C 11/00

(52) U.S. Cl. 438/14; 118/713; 257/E21.521

(57) ABSTRACT

A substrate is disposed within a processing chamber. A nitrogen precursor and a group-III precursor are flowed into the processing chamber. A layer is deposited over the substrate with a thermal chemical-vapor-deposition process at an elevated temperature within the processing chamber using the nitrogen precursor and the group-III precursor. Light beams are directed to a surface of the layer and light spots corresponding to reflections of the light beams are received from the surface at a position-sensitive detector. Positions of the light spots on the position-sensitive detector are determined from photocurrent induced in a photodiode in the position-sensitive detector. A curvature of the layer is determined from the positions of the light spots.

### BACKGROUND OF THE INVENTION

The history of light-emitting diodes (“LEDs”) is sometimes characterized as a “crawl up the spectrum.” This is because the first commercial LEDs produced light in the infrared portion of the spectrum, followed by the development of red LEDs that used GaAsP on a GaAs substrate. This was, in turn, followed by the use of GaP LEDs with improved efficiency that permitted the production of both brighter red LEDs and orange LEDs. Refinements in the use of GaP then permitted the development of green LEDs, with dual GaP chips (one in red and one in green) permitting the generation of yellow light. Further improvements in efficiency in this portion of the spectrum were later enabled through the use of GaAlAsP and InGaAlP materials.

This evolution towards the production of LEDs that provide light at progressively shorter wavelengths has generally been desirable not only for its ability to provide broad spectral coverage but because diode production of short-wavelength light may improve the information storage capacity of optical devices like CD-ROMs. The production of LEDs in the blue, violet, and ultraviolet portions of the spectrum was largely enabled by the development of nitride-based LEDs, particularly through the use of GaN. While some modestly successful efforts had previously been made in the production of blue LEDs using SiC materials, such devices suffered from poor luminescence as a consequence of the fact that their electronic structure has an indirect bandgap.

While the feasibility of using GaN to create photoluminescence in the blue region of the spectrum has been known for decades, there were numerous barriers that impeded their practical fabrication. These included the lack of a suitable substrate on which to grow the GaN structures, generally high thermal requirements for growing GaN that resulted in various thermal-convection problems, and a variety of difficulties in efficient p-doping such materials. The use of sapphire as a substrate was not completely satisfactory because it provides approximately a 15% lattice mismatch with the GaN. Progress has subsequently been made in addressing many aspects of these barriers. For example, the use of a buffer layer of AlN or GaN formed from a metalorganic vapor has been helpful in accommodating the lattice mismatch. Further refinements in the production of Ga—N-based structures has included the use of AlGaN materials to form heterojunctions with GaN and particularly the use of InGaN, which causes the creation of defects that act as quantum wells to emit light efficiently at short wavelengths. Indium-rich regions have a smaller bandgap than surrounding material, and may be distributed throughout the material to provide efficient emission centers.

While some improvements have thus been made in the manufacture of such compound nitride semiconductor devices, it is widely recognized that a number of deficiencies yet exist in current manufacturing processes. Moreover, the high utility of devices that generate light at such wavelengths has caused the production of such devices to be an area of intense interest and activity. In view of these considerations, there is a general need in the art for improved methods and systems for fabricating compound nitride semiconductor devices.

### BRIEF SUMMARY OF THE INVENTION

Embodiments of the invention provide systems and methods for fabricating a compound nitride semiconductor structure. In systems of the invention, a housing defines a processing chamber having optical access between an interior of the processing chamber and an exterior of the processing chamber. A substrate holder is disposed in the interior of the processing chamber. A light source operates in combination with a position-sensitive detector and an optical train. The position-sensitive detector comprises a photodiode interfaced with a unit to determine a position of light incident on the position-sensitive detector from photocurrent induced in the photodiode. The optical train is disposed to direct light from the light source through the optical access to a surface of a substrate disposed on the substrate holder and to direct light reflected from the surface to the position-sensitive detector. The system also comprises a precursor-delivery system, a pressure-control system, and a temperature-control system. The precursor-control system is configured to introduce precursors into the processing chamber system and comprises a nitrogen-precursor source and a group-III precursor source. The pressure-control system maintains a selected pressure in the interior of the processing chamber. The temperature-control system maintains a selected temperature in the interior of the processing chamber.

In some embodiments, the position-sensitive detector comprises an intermediate semiconductor layer disposed between an n-type resistive layer and a p-type resistive layer. At least one electrode is disposed over the n-type resistive layer or the p-type resistive layer to detect the photocurrent. The intermediate semiconductor layer may comprise a silicon layer. The at least one electrode may sometimes comprise a first electrode and a second electrode. The first electrode is disposed over the n-type resistive layer or the p-type resistive layer to detect a component of the photocurrent in a first direction. The second electrode is disposed over the n-type resistive layer or the p-type resistive layer to detect a component of the photocurrent in a second direction. The second direction is different from the first direction, permitting the position of light incident on the position-sensitive detector to be determined in two dimensions. In an alternative embodiment, the position-sensitive detector comprises an array of photodiodes interfaced with a unit to determine the position of light incident on the position-sensitive detector from relative strengths of photocurrents induced in different elements of the array.

A controller may be provided in communication with the position-sensitive detector. The controller comprises instructions to determine a curvature of the substrate from respective positions of a plurality of light spots reflected from the surface of the substrate and detected by the position-sensitive detector. The controller may be also be in communication with the precursor-delivery system, the pressure-control system, and the temperature-control system. In such instances, the controller may further comprise instructions to change a pressure in the interior of the processing chamber with the pressure-control system, to change a temperature in the interior of the processing chamber with the temperature-control system, to change a flow rate of nitrogen precursor from the nitrogen-precursor source to the processing chamber with the precursor-delivery system, and/or to change a flow rate of group-III precursor from the group-III-precursor source to the processing chamber with the precursor-delivery system in accordance with the determined curvature.

The group-III precursor source may sometimes comprise a gallium precursor source. In some cases, the group-III precursor source comprises a plurality of precursor sources for different group-III precursors. An example of a suitable nitrogen precursor source is an NH₃ source. The light source may comprise a laser in some embodiments.

In methods of the invention, a substrate is disposed within a processing chamber. A nitrogen precursor and a group-III precursor are flowed into the processing chamber. A layer is deposited over the substrate with a thermal chemical-vapor-deposition process at an elevated temperature within the processing chamber using the nitrogen precursor and the group-III precursor. A plurality of light beams are directed to a surface of the layer. Light spots corresponding to reflections of the light beams are received from the surface at a position-sensitive detector, which comprises a photodiode. Positions of the light spots on the position-sensitive detector are determined from photocurrent induced in the photodiode. A curvature of the layer is determined from the determined positions of the light spots.

In some instances, the position-sensitive detector comprises an intermediate semiconductor layer disposed between an n-type resistive layer and p-type resistive layer. At least one electrode is disposed over the n-type resistive layer or the p-type resistive layer. Positions of the light spots are then determined by detecting the photocurrent with the at least one electrode. The intermediate layer may comprise a silicon layer in some embodiments. The at least one electrode may comprise a first electrode disposed over the n-type resistive layer or the p-type resistive layer and a second electrode disposed over the n-type resistive layer or the p-type resistive layer. In such cases, positions of the light spots may be determined by detecting a component of the photocurrent in a first direction with the first electrode and detecting a component of the photocurrent in a second direction with the second electrode; the second direction is different from the first direction. In other embodiments, the position-sensitive detector comprises an array of photodiodes. This permits positions of the light spots to be determined from relative strengths of photocurrents induced in different elements of the array.

In some embodiments, a pressure in the processing chamber may be changed, a temperature in the processing chamber may be changed, a flow rate of nitrogen precursor into the processing chamber may be changed, and/or a flow rate of group-III precursor into the processing chamber may be changed in accordance with the determined curvature.

As for the system embodiments, examples of suitable group-III precursor sources comprise gallium precursor sources and examples of suitable nitrogen precursor sources comprise NH₃ sources. In certain embodiments, the group-III precursor source comprises a plurality of precursor sources for different group-III precursors.

### BRIEF DESCRIPTION OF THE DRAWINGS

A further understanding of the nature and advantages of the present invention may be realized by reference to the remaining portions of the specification and the drawings wherein like reference numerals are used throughout the several drawings to refer to similar components. In some instances, a sublabel is associated with a reference numeral and follows a hyphen to denote one of multiple similar components. When reference is made to a reference numeral without specification to an existing sublabel, it is intended to refer to all such multiple similar components.

FIG. 1 provides a schematic illustration of a structure of a GaN-based LED;

FIGS. 2A and 2B illustrate how physical differences between a substrate and material deposited on a substrate may result in shape distortions of nitride-based structures;

FIG. 3 is a simplified representation of an exemplary CVD apparatus that may be used in implementing certain embodiments of the invention;

FIG. 4 is a schematic illustration of techniques used for measuring stress in a substrate during processing;

FIG. 5 provides a cross-sectional illustration of a lateral-effect position-sensitive detector that may be used in performing stress measurements in embodiments of the invention;

FIG. 6 provides an illustration of a duolateral position-sensitive detector that may be used in performing stress measurements in embodiments of the invention;

FIG. 7 provides an illustration of a quad-cell two-dimensional position-sensitive detector that may be used in performing stress measurements in other embodiments of the invention; and

FIG. 8 is a flow diagram that summarizes certain processes that may be performed in embodiments of the invention.

### DETAILED DESCRIPTION OF THE INVENTION

### 1. Overview

One of the difficulties mentioned above in fabricating nitride-based structures such as GaN structures is the accommodation of generally high thermal requirements for growth of GaN. Historically, this made the identification of a suitable substrate difficult, with the art more recently focusing on ways in which the use of sapphire Al₂O₃ may be accommodated. Sapphire is not an ideal substrate because there is a significant lattice mismatch with deposited nitride layers; in the specific case of GaN, this lattice mismatch is approximately 15%. While the use of a nitride buffer layer has been helpful in accommodating the lattice mismatch, both the lattice mismatch and other physical differences between the sapphire substrate and overlying nitride layer result in distortions of resulting structures.

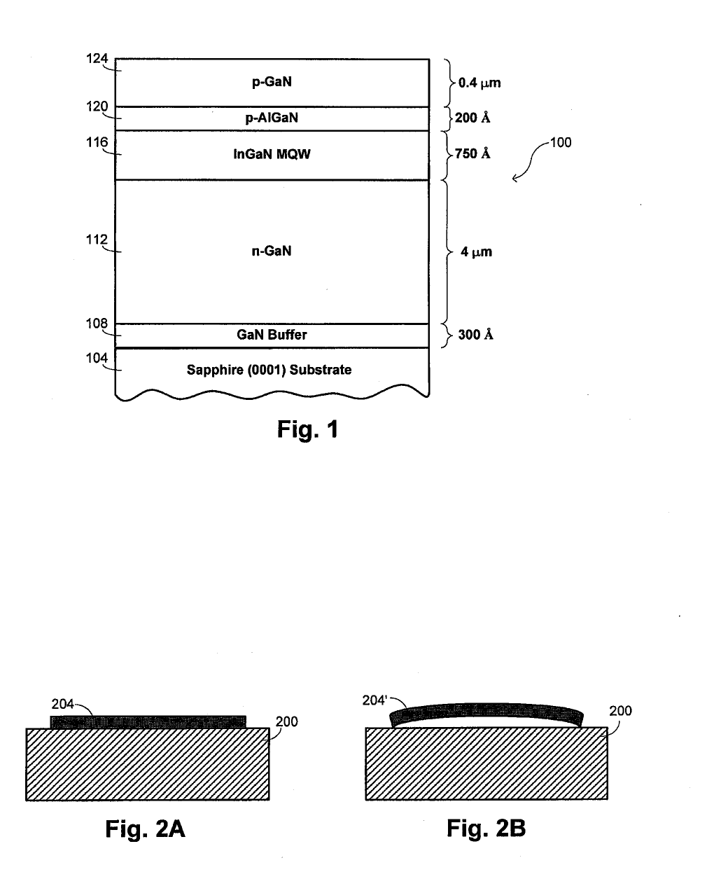

One typical nitride-based structure is illustrated in FIG. 1 as a GaN-based LED structure 100. It is fabricated over a sapphire (0001) substrate 104. An n-type GaN layer 112 is deposited over a GaN buffer layer 108 formed over the substrate. An active region of the device is embodied in a multi-quantum-well layer 116, shown in the drawing to comprise an InGaN layer. A pn junction is formed with an overlying p-type AlGaN layer 120, with a p-type GaN layer 124 acting as a contact layer.

A typical fabrication process for such an LED may use a metalorganic chemical-vapor-deposition (“MOCVD”) process that follows cleaning of the substrate 104 in a processing chamber. The MOCVD deposition is accomplished by providing flows of suitable precursors to the processing chamber and using thermal processes to achieve deposition. For example, a GaN layer may be deposited using Ga and N precursors, perhaps with a flow of a fluent gas like N₂, H₂, and/or NH₃; an InGaN layer may be deposited using Ga, N, and In precursors, perhaps with a flow of a fluent gas; and an AlGaN layer may be deposited using Ga, N, and Al precursors, also perhaps with a flow of a fluent gas. In the illustrated structure 100, the GaN buffer layer 108 has a thickness of about 300 Å, and may have been deposited at a temperature of about 550° C. Subsequent deposition of the n-GaN layer 112 is typically performed at a higher temperature, such as around 1050° C. in one embodiment. The n-GaN layer 112 is relatively thick, with deposition of a thickness on the order of 4 μm requiring about 140 minutes. The InGaN multi-quantum-well layer 116 may have a thickness of about 750 Å, which may be deposited over a period of about 40 minutes at a temperature of about 750° C. The p-AlGaN layer 120 may have a thickness of about 200 Å, which may be deposited in about five minutes at a temperature of 950° C. The thickness of the contact layer 124 that completes the structure may be about 0.4 μm in one embodiment, and may be deposited at a temperature of about 1050° C. for around 25 minutes.

An illustration of the type of shape distortion that may result from such a deposition process is illustrated schematically with FIGS. 2A and 2B. As illustrated with the description of the structure shown in FIG. 1, fabrication processes of nitride structures may include a number of temperature changes and consistently take place at temperatures elevated from normal operational temperatures of the completed structures. In addition to there being a lattice mismatch between sapphire and GaN, such materials have different coefficients of thermal expansion, causing differences in thermal expansion at different processing temperatures. This effect is generally even more significant than the lattice mismatch in causing shape distortions. The effect is illustrated schematically in FIGS. 2A and 2B. In these drawings, element 200 is a substrate holder, over which the structure 204 being fabricated is disposed. The two drawings are at different points in time during a fabrication process, with FIG. 2B corresponding to a later time than FIG. 2A and at a lower temperature than FIG. 2A. Such a sequence may occur in a variety of different fabrication processes for nitride structures. In the specific case of the structure shown in FIG. 1, for example, FIG. 2A may correspond to a point in time during epitaxy of the n-GaN layer 112 when the temperature is about 1050° C. and FIG. 2B may correspond to a point in time during growth of the InGaN active region 116 when the temperature is about 750° C. Notably, FIG. 2B could also correspond to a point in time after the entire structure has been fabricated and cooled down to room temperature.

It is evident from the drawing that the structure 204′ at the cooler temperature is deformed with a center that is bowed upwards when compared with the structure 204 at the higher temperature. This bowing results from the differential thermal expansion between GaN and sapphire. Deposition may occur with a flat geometry at the temperatures used for GaN growth as shown in FIG. 2A. But when the structure is subsequently cooled for deposition of the InGaN active region, the substrate center bows upwards and becomes somewhat cooler than the edges. This temperature nonuniformity over the surface of the structure results in a nonuniformity in indium distribution in the deposited InGaN, with indium-rich regions tending to form at the center of the substrate and indium-poor regions tending to form at the periphery of the substrate. In turn, this nonuniformity in indium distribution translates into wavelength and light-output variations for devices formed across the structure, limiting the scale-up of the process for producing these materials.

Embodiments of the invention provide methods and systems that permit monitoring of the stress characteristics in situ as it is deposited. This monitoring not only permits the collection of data that may be used in refining future processes, it also permits modifications to be made to the process being implemented as part of a feedback arrangement. Monitoring of the stress characteristics may be performed by monitoring the degree of bowing exhibited by a layer during processing as a surrogate for a quantitative measure of the stress in the layer.

### 2. Exemplary Substrate Processing System

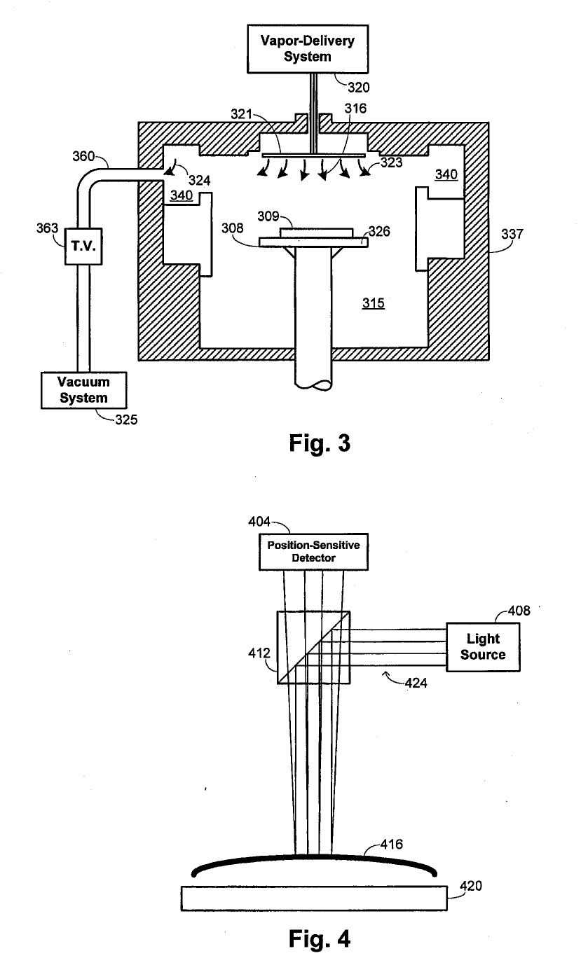

FIG. 3 is a simplified diagram of an exemplary chemical vapor deposition (“CVD”) system, illustrating the basic structure of a chamber in which individual deposition steps can be performed. This system is suitable for performing thermal, sub-atmospheric CVD (“SACVD”) processes, as well as other processes, such as reflow, drive-in, cleaning, etching, deposition, and gettering processes. In some instances multiple-step processes can still be performed within an individual chamber before removal for transfer to another chamber. The major components of the system include, among others, a vacuum chamber 315 that receives process and other gases from a gas or vapor delivery system 320, a vacuum system 325, and a control system (not shown). These and other components are described in more detail below. While the drawing shows the structure of only a single chamber for purposes of illustration, it will be appreciated that multiple chambers with similar structures may be provided as part of a cluster tool, each tailored to perform different aspects of certain overall fabrication processes.

The CVD apparatus includes an enclosure assembly 337 that forms vacuum chamber 315 with a gas reaction area 316. A gas distribution structure 321 disperses reactive gases and other gases, such as purge gases, toward one or more substrates 309 held in position by a substrate support structure 308. Between gas distribution structure 321 and the substrate 309 is gas reaction area 316. Heaters 326 can be controllably moved between different positions to accommodate different deposition processes as well as for an etch or cleaning process. A center board (not shown) includes sensors for providing information on the position of the substrate.

Different structures may be used for heaters 326. For instance, some embodiments of the invention advantageously use a pair of plates in close proximity and disposed on opposite sides of the substrate support structure 308 to provide separate heating sources for the opposite sides of one or more substrates 309. Merely by way of example, the plates may comprise graphite or SiC in certain specific embodiments. In another instance, the heaters 326 include an electrically resistive heating element (not shown) enclosed in a ceramic. The ceramic protects the heating element from potentially corrosive chamber environments and allows the heater to attain temperatures up to about 1200° C. In an exemplary embodiment, all surfaces of heaters 326 exposed to vacuum chamber 315 are made of a ceramic material, such as aluminum oxide (Al₂O₃ or alumina) or aluminum nitride. In another embodiment, the heaters 326 comprises lamp heaters. Alternatively, a bare metal filament heating element, constructed of a refractory metal such as tungsten, rhenium, iridium, thorium, or their alloys, may be used to heat the substrate. Such lamp heater arrangements are able to achieve temperatures greater than 1200° C., which may be useful for certain specific applications.

Reactive and carrier gases are supplied from the gas or vapor delivery system 320 through supply lines to the gas distribution structure 321. In some instances, the supply lines may deliver gases into a gas mixing box to mix the gases before delivery to the gas distribution structure. In other instances, the supply lines may deliver gases to the gas distribution structure separately, such as in certain showerhead configurations described below. The gas or vapor delivery system 320 includes a variety of sources and appropriate supply lines to deliver a selected amount of each source to chamber 315 as would be understood by a person of skill in the art. Generally, supply lines for each of the sources include shut-off valves that can be used to automatically or manually shut-off the flow of the gas into its associated line, and mass flow controllers or other types of controllers that measure the flow of gas or liquid through the supply lines. Depending on the process run by the system, some of the sources may actually be liquid or solid sources rather than gases. When liquid sources are used, gas delivery system includes a liquid injection system or other appropriate mechanism (e.g., a bubbler) to vaporize the liquid. Vapor from the liquids is then usually mixed with a carrier gas as would be understood by a person of skill in the art. During deposition processing, gas supplied to the gas distribution structure 321 is vented toward the substrate surface (as indicated by arrows 323), where it may be uniformly distributed radially across the substrate surface in a laminar flow.

Purging gas may be delivered into the vacuum chamber 315 from gas distribution structure 321 and/or from inlet ports or tubes (not shown) through the bottom wall of enclosure assembly 337. Purge gas introduced from the bottom of chamber 315 flows upward from the inlet port past the heater 326 and to an annular pumping channel 340. Vacuum system 325 which includes a vacuum pump (not shown), exhausts the gas (as indicated by arrows 324) through an exhaust line 360. The rate at which exhaust gases and entrained particles are drawn from the annular pumping channel 340 through the exhaust line 360 is controlled by a throttle valve system 363.

The temperature of the walls of deposition chamber 315 and surrounding structures, such as the exhaust passageway, may be further controlled by circulating a heat-exchange liquid through channels (not shown) in the walls of the chamber. The heat-exchange liquid can be used to heat or cool the chamber walls depending on the desired effect. For example, hot liquid may help maintain an even thermal gradient during a thermal deposition process, whereas a cool liquid may be used to remove heat from the system during other processes, or to limit formation of deposition products on the walls of the chamber. Gas distribution manifold 321 also has heat exchanging passages (not shown). Typical heat-exchange fluids water-based ethylene glycol mixtures, oil-based thermal transfer fluids, or similar fluids. This heating, referred to as heating by the “heat exchanger”, beneficially reduces or eliminates condensation of undesirable reactant products and improves the elimination of volatile products of the process gases and other contaminants that might contaminate the process if they were to condense on the walls of cool vacuum passages and migrate back into the processing chamber during periods of no gas flow.

The system controller controls activities and operating parameters of the deposition system. The system controller may include a computer processor and a computer-readable memory coupled to the processor. The processor executes system control software, such as a computer program stored in memory. The processor operates according to system control software (program), which includes computer instructions that dictate the timing, mixture of gases, chamber pressure, chamber temperature, microwave power levels, pedestal position, and other parameters of a particular process. Control of these and other parameters is effected over control lines that communicatively couple the system controller to the heater, throttle valve, and the various valves and mass flow controllers associated with gas delivery system 320.

### 3. Stress Monitoring

Embodiments of the invention make use of photodiode position sensing to evaluate a degree of bowing of a layer during processing, and thereby to determine an indication of stress in the layer. An illustration of the basic technique is provided with FIG. 4. Evaluation of the bowing makes use of optical illumination of the substrate in situ in the processing chamber during processing. Optical access to the substrate may be provided in a number of different ways, most easily by providing a window in the process chamber through which light may be transmitted and received. A variety of optical elements may be included within or outside the chamber to direct the light as desired. When optical access is provided with a window, it is generally desirable for the window to be small so that it has minimal disturbance on the processing characteristics taking place within the chamber.

Details of how optical access is provided are not shown in FIG. 4, which illustrates how optical information may be used to infer information about the stress characteristics as a layer is deposited. The substrate 416 over which the layer is being formed is provided over a substrate holder 420 using a configuration like that described in connection with FIG. 3. An array of light spots are directed to the surface of the layer, with FIG. 4 showing a light source 408 used to generate a plurality of light beams 424 that are focused by an optical arrangement 412 onto the layer surface. In this example, the optical arrangement 412 comprises a prism that permits collection of light reflected from the layer surface to be collected by a position-sensitive detector 404, but other optical arrangements may be used in various alternative embodiments. The light beams 424 may preferably be provided as highly collimated beams, such as may be generated with a variety of laser systems known to those of skill in the art.

The manner in which light is detected by the position-sensitive detector 404 depends on the direction of the light comprised by the reflected spots, which may moreover change over time as the bowing characteristics change. As the reflected spots move away from each other, the layer is acquiring a more convex shape, and as the reflected spots move together, the layer is acquiring a less convex or more concave shape. The position-sensitive detector 404 may be provided in communication with a computational unit that includes programming to detect changes in the spot positions, perhaps quantifying the degree of separation of the reflected spots and the degree to which that separation changes in correlating the measurements to determinations of bowing or stress.

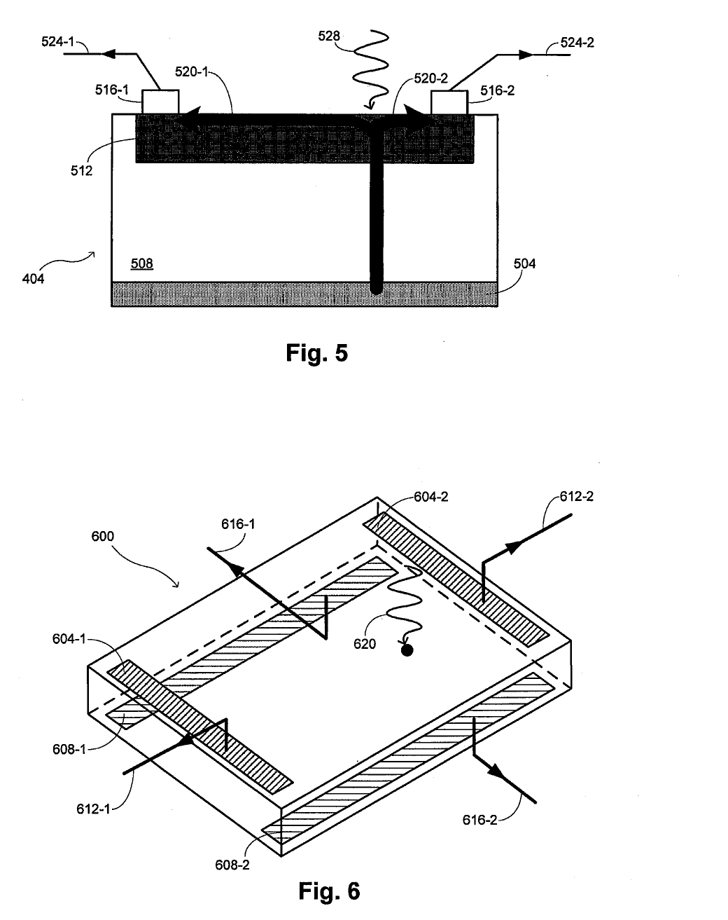

In embodiments of the invention, the position-sensitive detector 404 comprises a photodiode structure. As explained in detail below, there are different implementations that may be used for the position-sensitive detector in various embodiments. FIG. 5 provides an illustration of a lateral effect structure. In such an embodiment, the position-sensitive detector 404 comprises a photodiode created by a pn junction. In a specific implementation, an n-type silicon substrate 508 separates two resistive layers, an ion-implanted n-type layer 504 and an ion-implanted p-type layer 512.

Contacts 516 are formed over the p-type resistive layer 512 to measure output photocurrents. An incident light spot 528 within the spectral range of silicon generates photocurrents 520 that flow from the position of incidence through the resistive layers to the electrodes 516. When the ion-implanted layers 504 and 512 are substantially uniform, the photogenerated current at each electrode 516 is inversely proportional to the separation between the position of incidence of the light 528 and the position of each electrode 516. Currents 524 measured at each of the electrodes thus define the position of incidence of the light 528.

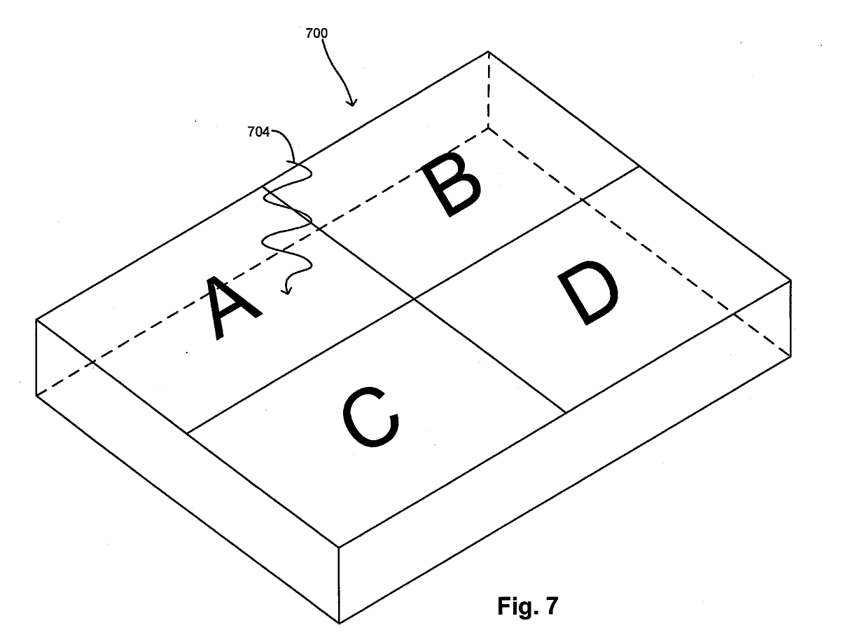

This basic concept of operation may be extended to multiple dimensions, as illustrated schematically in FIG. 6. In this illustration, a two-dimensional position-sensitive detector 600 is provided with a pn-junction photodiode structure like that illustrated for a single dimension in FIG. 5. In this instance, pairs of electrodes 612 are provided in a first direction and pairs of electrodes 616 are provided in a second direction. In the illustration, the first and second directions are substantially orthogonal, but any nonlinear combination of directions may more generally be used in defining a two-dimensional array of coordinates for use in specifying positions.

A light spot 620 incident on the structure 600 again causes photogenerated currents to flow from the incident point to the electrodes 612 and 616, with the magnitude of the currents being inversely proportion to the separation of the respective electrodes 612 and 616 from the incident point. In this instance, currents measured at electrodes 612 may thus be used to determine a coordinate position of the incident point in the first direction and currents measured at electrodes 616 may be used to determine a coordinate position of the incident point in the second direction. This information thus defines the two-dimensional position of the incident point.

In still other embodiments, the position-sensitive detector may comprise a plurality of photodiode structures, as illustrated schematically in FIG. 7. In this illustration, the position-sensitive detector 700 comprises four photodiode elements labeled “A,” “B,” “C,” and “D.” The photodiode structures respond to incident light 704 in a manner similar to that described in connection with FIGS. 5 and 6. Use of a multielement photodiode structure permits the centroid of the incident point to be determined by comparing signals from each of the distinct elements. In the case of a four-element structure like that shown in FIG. 7, displacements in two directions may be determined from measured signal strengths I_{A}, I_{B}, I_{C}, and I_{D}, which respectively correspond to the signal strength in quadrants A, B, C, and D:

$${q}_{1} ≡ \frac{( {I}_{A} + {I}_{B} ) - ( {I}_{C} + {I}_{D} )}{{I}_{A} + {I}_{B} + {I}_{C} + {I}_{D}}$$

$${q}_{2} ≡ \frac{( {I}_{B} + {I}_{D} ) - ( {I}_{A} + {I}_{C} )}{{I}_{A} + {I}_{B} + {I}_{C} + {I}_{D}} .$$

The use of photodiode arrangements to determine spot positions have a number of benefits that are particularly relevant to applications involving fabrication of nitride structures. In particular, such arrangements may be produced more compactly and for considerably less cost than a variety of alternative arrangements, such as might be provided with array of charge-coupled devices. The ability to produce more compact structures results in less interference with fabrication processes taking place within the processing chamber since optical access requirements are relatively modest. Relatively large structures like those that result when arrays of charge-coupled devices are formed require more optical access to the processing chamber, with mechanisms that provide such optical access having a greater risk of disturbing the processes taking place. This may lead to nonuniformities in the structures that are produced, which, in the specific case of fabricated nitride light-emitting structures may cause variations in wavelength and light output across the structure that restrict scale-up opportunities. While some other structures, like charge-coupled-device arrays, may have greater precision in defining spot positions, this is a less important consideration in nitride applications when the stress distortions in layers may be relatively severe. With the fabrication of other types of structures, the calculus evaluating the relative considerations may be different.

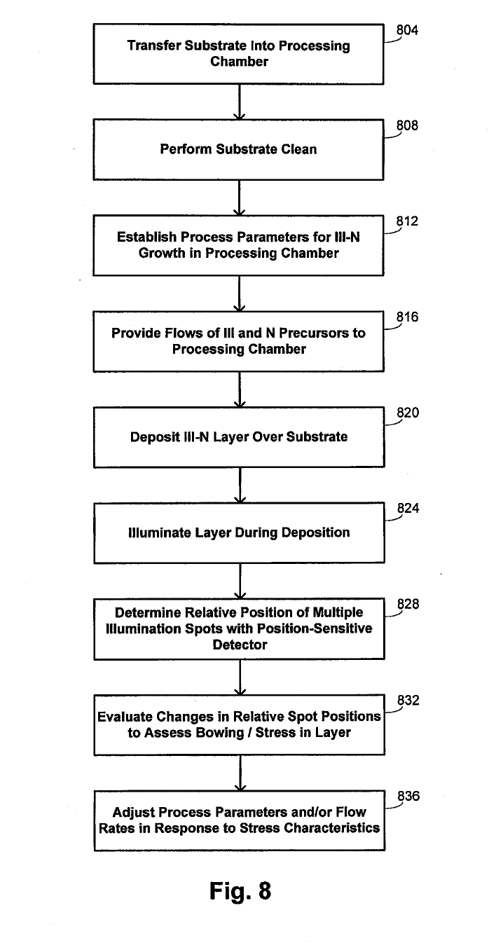

FIG. 8 is a flow diagram that summarizes different types of fabrication processes that may accordingly use the position-sensitive detector structures in monitoring stress characteristics. These fabrication processes are illustrated in the flow diagram for the fabrication of group-III nitride structures. The process begins at block 804 by transferring a substrate into a substrate processing chamber. For deposition of a nitride structure, the substrate may comprise sapphire, although other materials that may be used include SiC, Si, spinel, lithium gallate, ZnO, and others. The substrate is cleaned at block 808, after which process parameters suitable for growth of a nitride layer may be established at block 812. Such process parameters may include temperature, pressure, and the like to define an environment within the processing chamber appropriate for thermal deposition of a nitride layer. Flows of precursors are provided at block 816 to deposit a III-N layer over the substrate at block 820. The precursors include a nitrogen source and a source for a first group-III element such as Ga. For instance, suitable nitrogen precursors include NH₃ and suitable Ga precursors include trimethyl gallium (“TMG”). The first group-III element may sometimes comprise a plurality of distinct group-III elements such as Al and Ga, in which case a suitable Al precursor may be trimethyl aluminum (“TMA”); in another example, the plurality of distinct group-III elements includes In and Ga, in which case a suitable In precursor may be trimethyl indium (“TMI”). A flow of a carrier gas such as N₂ and/or H₂ may also be included.

During deposition, the layer may be illuminated at block 824 with a plurality of light spots, permitting relative positions of reflected illumination spots to be determined with a position-sensitive detector at block 828 and as described in detail above. As previously noted, the light spots may be provided by directing highly collimated optical beams, such as may be provided by laser sources. Changes in the relative spot positions reflected from the layer may be evaluated at block 832 to assess changes in the shape of the layer as it is deposited. Such shape changes are indicative of stress characteristics within the layer and are manifested by increasing separation of the reflected spot positions as the shape becomes more convex and by decreasing separation of the reflected spot positions as the shape becomes less convex. Such evaluations during processing permit adjustments to be made in the process parameters and/or flow rates at block 836 to compensate for the particular stress characteristics.

In general, the processing conditions used for deposition of a III-N layer may vary depending on specific applications. The following table provides exemplary processing conditions and precursor flow rates that are generally suitable in the growth of nitride semiconductor structures using the methods and systems described above:

| Parameter | Value |
|---|---|
| Temperature (° C.) | 500–1500 |
| Pressure (torr) | 50–1000 |
| TMG flow (sccm) | 0–50 |
| TMA flow (sccm) | 0–50 |
| TMI flow (sccm) | 0–50 |
| PH₃ flow (sccm) | 0–1000 |
| AsH₃ flow (sccm) | 0–1000 |
| NH₃ flow (sccm) | 100–100,000 |
| N₂ flow (sccm) | 0–100,000 |
| H₂ flow (sccm) | 0–100,000 |

As will be evident from the preceding description, a process might not use flows of all the precursors in any given process. For example, growth of GaN might use flows of TMG, NH₃, and N₂ in one embodiment; growth of AlGaN might use flows of TMG, TMA, NH₃, and H₂ in another embodiment, with the relative flow rates of TMA and TMG selected to provide a desired relative Al:Ga stoichiometry of the deposited layer; and growth of InGaN might use flows of TMG, TMI, NH₃, N₂, and H₂ in still another embodiment, with relative flow rates of TMI and TMG selected to provide a desired relative In:Ga stoichiometry of the deposited layer.

Thus, having described several embodiments, it will be recognized by those of skill in the art that various modifications, alternative constructions, and equivalents may be used without departing from the spirit of the invention. Accordingly, the above description should not be taken as limiting the scope of the invention, which is defined in the following claims.

What is claimed is:

1. A system for fabricating a compound nitride semiconductor structure, the system comprising:
a housing defining a processing chamber having optical access between an interior of the processing chamber and an exterior of the processing chamber;
a substrate holder disposed in the interior of the processing chamber;
a light source;
a position-sensitive detector comprising a photodiode interfaced with a unit to determine a position of light incident on the position-sensitive detector from photocurrent induced in the photodiode;
an optical train disposed to direct light from the light source through the optical access to a surface of a substrate disposed on the substrate holder and to direct light reflected from the surface to the position-sensitive detector;
a precursor-delivery system configured to introduce precursors into the processing chamber, the precursor-delivery system comprising:
a nitrogen-precursor source; and
a group-III-precursor source;
a pressure-control system for maintaining a selected pressure in the interior of the processing chamber; and
a temperature-control system for maintaining a selected temperature in the interior of the processing chamber.

2. The system recited in claim 1 wherein the position-sensitive detector comprises:
an intermediate semiconductor layer disposed between an n-type resistive layer and a p-type resistive layer; and
at least one electrode disposed over the n-type resistive layer or the p-type resistive layer to detect the photocurrent.

3. The system recited in claim 2 wherein the intermediate semiconductor layer comprises a silicon layer.

4. The system recited in claim 2 wherein the at least one electrode comprises:
a first electrode disposed over the n-type resistive layer or the p-type resistive layer to detect a component of the photocurrent in a first direction; and
a second electrode disposed over the n-type resistive layer or the p-type resistive layer to detect a component of the photocurrent in a second direction,
wherein the second direction is different from the first direction, whereby the position of light incident on the position-sensitive detector is determined in two dimensions.

5. The system recited in claim 1 wherein the position-sensitive detector comprises an array of photodiodes interfaced with a unit to determine the position of light incident on the position-sensitive detector from relative strengths of photocurrents induced in different elements of the array.

6. The system recited in claim 1 further comprising a controller in communication with the position-sensitive detector, wherein the controller comprises instructions to determine a curvature of the substrate from respective positions of a plurality of light spots reflected from the surface of the substrate and detected by the position-sensitive detector.

7. The system recited in claim 6 wherein:
the controller is further in communication with the precursor-delivery system, the pressure-control system, and the temperature-control system; and
the controller further comprises instructions to change a pressure in the interior of the processing chamber with the pressure-control system, to change a temperature in the interior of the processing chamber with the temperature-control system, to change a flow rate of nitrogen precursor from the nitrogen-precursor source to the processing chamber with the precursor-delivery system, and/or to change a flow rate of group-III precursor from the group-III-precursor source to the processing chamber with the precursor-delivery system in accordance with the determined curvature.

8. The system recited in claim 1 wherein the group-III precursor source comprises a gallium precursor source.

9. The system recited in claim 1 wherein the group-III precursor source comprises a plurality of precursor sources for different group-III precursors.

10. The system recited in claim 1 wherein the nitrogen precursor source comprises an NH₃ source.

11. The system recited in claim 1 wherein the light source comprises a laser.

12. A method for fabricating a compound nitride semiconductor structure, the method comprising:
disposing a substrate within a processing chamber;
flowing a nitrogen precursor into the processing chamber;
flowing a group-III precursor into the processing chamber;
depositing a layer over the substrate with a thermal chemical-vapor-deposition process at an elevated temperature within the processing chamber using the nitrogen precursor and the group-III precursor;
directing a plurality of light beams to a surface of the layer;
receiving light spots corresponding to reflections of the light beams from the surface at a position-sensitive detector, the position-sensitive detector comprising a photodiode;
determining positions of the light spots on the position-sensitive detector from photocurrent induced in the photodiode; and
determining a curvature of the layer from the determined positions of the light spots.

13. The method recited in claim 12 wherein:
the position-sensitive detector comprises:
an intermediate semiconductor layer disposed between an n-type resistive layer and a p-type resistive layer; and
at least one electrode disposed over the n-type resistive layer or the p-type layer; and
determining positions of the light spots comprises detecting the photocurrent with the at least one electrode.

14. The method recited in claim 13 wherein the intermediate semiconductor layer comprises a silicon layer.

15. The method recited in claim 13 wherein:
the at least one electrode comprises:
a first electrode disposed over the n-type resistive layer or the p-type resistive layer; and
a second electrode disposed over the n-type resistive layer or the p-type resistive layer;
determining positions of the light spots comprises:
detecting a component of the photocurrent in a first direction with the first electrode; and
detecting a component of the photocurrent in a second direction with the second electrode; and
the second direction is different from the first direction.

16. The method recited in claim 12 wherein:
the position-sensitive detector comprises an array of photodiodes; and
determining positions of the light spots comprises determining positions of the light spots from relative strengths of photocurrents induced in different elements of the array.

17. The method recited in claim 12 further comprising changing a pressure in the processing chamber, changing a temperature in the processing chamber, changing a flow rate of nitrogen precursor into the processing chamber, and/or changing a flow rate of group-III precursor into the processing chamber in accordance with the determined curvature.

18. The method recited in claim 12 wherein the group-III precursor source comprises a gallium precursor source.

19. The method recited in claim 12 wherein the group-III precursor source comprises a plurality of precursor sources for different group-III precursors.

20. The method recited in claim 12 wherein the nitrogen precursor source comprises an NH₃ source.
